(19) United States
(12) Patent Application Publication
(10) Pub. No.: US 2026/0324271 A1
(43) Pub. Date: Oct. 15, 2026

(54) ELECTRONIC APPARATUS AND METHOD OF MANUFACTURING THE SAME

(71) Applicant: Samsung Display Co., Ltd., Yongin-si (KR)

(72) Inventor: KUHYUN KANG, Yongin-si (KR)

(21) Appl. No.: 19/423,576

(22) Filed: Dec. 17, 2025

(30) Foreign Application Priority Data
Apr. 11, 2025 (KR) 10-2025-0047214

(51) Int. Cl. H10K 59/80; H10K 59/12

(52) U.S. Cl. CPC H10K 59/8793; H10K 59/1201; H10K 59/872

(57) ABSTRACT

An electronic apparatus includes: a display panel; a window including a perimeter including four straight sides and four corner sides arranged between the straight sides and connecting the straight sides adjacent to each other in plan view; a housing under the display panel and accommodating the display panel; a phase retardation layer on the window; a polarizing plate on the phase retardation layer and including a first layer, a second layer on the first layer, and a third layer on the second layer; and an adhesive layer between the window and the phase retardation layer to bond the window to the phase retardation layer. A side surface of the second layer includes a first side portion adjacent to the straight sides and a second side portion adjacent to the corner sides in plan view. The first side portion has a shape different from a shape of the second side portion.

### CROSS-REFERENCE TO RELATED APPLICATION

The present application claims priority to and the benefit of Korean Patent Application No. 10-2025-0047214, filed on Apr. 11, 2025, in the Korean Intellectual Property Office, the entire disclosure of which is incorporated herein by reference.

### BACKGROUND

### 1. Field

One or more embodiments of the present disclosure relate to an electronic apparatus and a method of manufacturing the same. For example, one or more embodiments of the present disclosure relate to an electronic apparatus with improved reliability.

### 2. Description of the Related Art

With the development of various display devices such as televisions, monitors, smartphones, and/or tablet computers, technologies to provide images to users have been continuously advancing. These display devices include one or more display panels that displays images, and the display panel may include (e.g., be) a liquid crystal display panel, an organic light emitting display panel, an electrowetting display panel, or an electrophoretic display panel.

In addition, the display device may include a window to protect the display panel from external impact or contamination. The window is fabricated by a laser cutting process and then attached to the display panel, and thus, durability and visibility of the display device are enhanced.

### SUMMARY

One or more aspects of embodiments of the present disclosure are directed toward an electronic apparatus including a window and a method of manufacturing the electronic apparatus. Additional aspects will be set forth in part in the description which follows and, in part, will be apparent from the description, or may be learned by practice of the presented embodiments.

According to one or more embodiments of the present disclosure, an electronic apparatus includes a display panel including an active area and a peripheral area adjacent to the active area, a window on (e.g., arranged on) the display panel and including a perimeter including four straight sides and four corner sides arranged between the straight sides and connecting the straight sides adjacent to each other if (e.g., when) viewed in a plane (e.g., in plan view), a housing under (e.g., arranged under) the display panel and accommodating the display panel, a phase retardation layer on (e.g., arranged on) the window, a polarizing plate on (e.g., arranged on) the phase retardation layer and including a plurality of layers, and an adhesive layer between (e.g., arranged between) the window and the phase retardation layer to bond the window to the phase retardation layer. The layers (i.e., the plurality of layers) include a first layer, a second layer on (e.g., arranged on) the first layer, and a third layer on (e.g., arranged on) the second layer, a side surface of the second layer includes a first side portion adjacent to the straight sides and a second side portion adjacent to the corner sides if (e.g., when) viewed in the plane (e.g., in plan view), and the first side portion has a shape different from a shape of the second side portion.

The side surface of the second layer is protruded in a direction away from the active area beyond a side surface of the first layer and a side surface of the third layer.

The side surface of the second layer has a curved surface.

The second side portion includes a bent portion bent toward the third layer.

The bent portion is arranged at a same plane as at least a portion of the third layer.

An end of the bent portion includes a curved surface.

The adhesive layer includes a pressure sensitive adhesive.

In one or more embodiments, the polarizing plate further includes a polarizing layer between (e.g., arranged between) the first layer and the second layer, and the polarizing layer includes polyvinyl alcohol.

The polarizing plate includes a triacetylcellulose layer (the first layer), a polyolefin film (the second layer) on (e.g., arranged on) the triacetylcellulose layer, and a protective film (the third layer) on (e.g., arranged on) the polyolefin film, and a side surface of the polyolefin film adjacent to each of the straight sides if (e.g., when) viewed in a cross-section is different (e.g., in shape) from a side surface of the polyolefin film adjacent to the corner sides if (e.g., when) viewed in a cross-section.

According to one or more embodiments of the present disclosure, there is provided a method of manufacturing an electronic apparatus. The manufacturing method of the electronic apparatus includes providing a display panel, providing a window including a first area and a second area around (e.g., surrounding) an edge of the first area if (e.g., when) viewed in a plane and including a perimeter including four straight sides and four corner sides arranged between the straight sides and connecting the straight sides adjacent to each other if (e.g., when) viewed in the plane, sequentially providing an adhesive layer and an optical layer on the window to form a preliminary window module, cutting the preliminary window module to form a window module, and bonding the display panel to the window module. The cutting of the preliminary window module to form the window module includes performing a first irradiation operation to irradiate a first laser beam along a first irradiation line defined along the second area, performing a second irradiation operation to irradiate a second laser beam along a second irradiation line defined along the second area, and performing a third irradiation operation to irradiate a third laser beam along a third irradiation line defined along the second area. At least one selected from among the first, second, and third irradiation lines includes a portion separated from the other irradiation lines, and the separated portion overlaps each of the corner sides if (e.g., when) viewed in the plane.

A separation distance of the separated portion from the other irradiation lines varies depending on a curvature of the corner sides if (e.g., when) viewed in the plane.

The second irradiation operation is performed after the first irradiation operation, the third irradiation operation is performed after the second irradiation operation, a power of the second laser beam is less than a power of the first laser beam, and a power of the third laser beam is less than the power of the second laser beam.

In one or more embodiments, the second irradiation line is located farther from the first area than first irradiation line is, and the third irradiation line coincides with the first irradiation line.

In one or more embodiments, the second irradiation line is located closer to the first area than first irradiation line is, and the third irradiation line coincides with the first irradiation line.

In one or more embodiments, the second irradiation line coincides with the first irradiation line, and the third irradiation line is located farther from the first area than first irradiation line is.

In one or more embodiments, the second irradiation line coincides with the first irradiation line, and the third irradiation line is located closer to the first area than first irradiation line is.

The optical layer includes a phase retardation layer, a triacetylcellulose layer on (e.g., arranged on) the phase retardation layer, a polyolefin film on (e.g., arranged on) the triacetylcellulose layer, and a protective film on (e.g., arranged on) the polyolefin film, and a first depth to which the first laser beam reaches is greater than a distance between an upper surface of the optical layer and an upper surface of the polyolefin film.

A portion of the triacetylcellulose layer is vaporized by an energy of the first laser beam, and a curved portion is formed in the polyolefin film due to a gas generated by the vaporization of the portion of the triacetylcellulose layer.

A second depth to which the second laser beam reaches is greater than a distance between the upper surface of the optical layer and an upper surface of the phase retardation layer.

A third depth to which the third laser beam reaches is smaller than a distance between the upper surface of the optical layer and a lower surface of the adhesive layer.

According to one or more embodiments of the present disclosure, as the laser beam whose power is gradually decreased is irradiated multiple times at a same location in the laser cutting process for the window, the power of the laser beam may be easily controlled or selected, and damage to window and cracks in the polarizing plate are reduced or prevented.

In addition, as the laser irradiation position is partially shifted to disperse the power of the laser beam in the corner area of the window, a difference in processing between the linear area and the corner area is reduced, and a processing precision is improved through more uniform cutting.

For example, embodiments of the present disclosure provide an integrated approach in which the structural configuration of the window module—including the window, adhesive layer, phase retardation layer, and multi-layer polarizing plate—is coordinated with a laser-based cutting process that employs multiple irradiation operations with controlled power and positional offsets. This combination enables precise edge formation in both linear and corner regions, minimizes or reduces thermal stress, and reduces the likelihood of cracks or delamination in the polarizing plate and adhesive layer. By controlling residual adhesive thickness and shaping side portions of the polarizing plate differently in straight and corner regions, the disclosed apparatus achieves improved durability, optical performance, and manufacturability.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the disclosure will become more apparent from the following description of example embodiments thereof with reference to the accompanying drawings, in which:

FIG. 1 is a block diagram of an electronic apparatus according to one or more embodiments of the present disclosure;

FIG. 2 is a schematic view of electronic apparatuses according to one or more embodiments of the present disclosure;

FIG. 3 is a perspective view of an electronic apparatus according to one or more embodiments of the present disclosure;

FIG. 4 is an exploded perspective view of an electronic apparatus according to one or more embodiments of the present disclosure;

FIG. 5 is a cross-sectional view of the electronic apparatus shown in FIG. 3 according to one or more embodiments of the present disclosure;

FIG. 6 is a cross-sectional view of a display panel shown in FIG. 5 according to one or more embodiments of the present disclosure;

FIG. 7 is a plan view of a window according to one or more embodiments of the present disclosure;

FIG. 8A is a cross-sectional view of a window module taken along the line I-I′ of FIG. 7 according to one or more embodiments of the present disclosure;

FIG. 8B is a cross-sectional view of a window module taken along the line II-II′ of FIG. 7 according to one or more embodiments of the present disclosure;

FIG. 9A is a cross-sectional view of a window module taken along the line I-I′ of FIG. 7 according to one or more embodiments of the present disclosure;

FIG. 9B is a cross-sectional view of a window module taken along the line II-II′ of FIG. 7 according to one or more embodiments of the present disclosure;

FIG. 10A is a plan view of a window module according to one or more embodiments of the present disclosure;

FIG. 10B-10I are cross-sectional views of processes of a method of manufacturing an electronic apparatus according to one or more embodiments of the present disclosure;

FIG. 11A-11C are cross-sectional views of processes of a method of manufacturing an electronic apparatus according to one or more embodiments of the present disclosure;

FIGS. 12A and 12B are each a plan view of a window module according to one or more embodiments of the present disclosure;

FIG. 13A-13D are each a schematic view illustrating a spacing relationship between irradiation lines according to one or more embodiments of the present disclosure; and

FIG. 14 is a schematic view illustrating a separation distance of irradiation lines in a corner area of a window according to one or more embodiments of the present disclosure.

### DETAILED DESCRIPTION

Embodiments of the present disclosure may be variously modified and realized in many different forms, and thus specific embodiments will be exemplified in the drawings and described in more detail hereinbelow. However, the present disclosure should not be limited to the specific disclosed forms, and should be construed to include all modifications, equivalents, or replacements included in the spirit and scope of the present disclosure.

In the present disclosure, it will be understood that if (e.g., when) an element (or area, layer, or portion) is referred to as being “on”, “connected to” or “coupled to” another element or layer, it may be directly on, connected or coupled to the other element or layer, or one or more intervening elements or layers may be present therebetween. In contrast, “directly on” may refer to that there are no additional intervening elements or layers between the element or layer and the other element or layer. In addition, if (e.g., when) a layer, a film, a region, a plate, and/or the like is referred to as being “under” or “below” another part, it may be “directly under” the other part, or one or more intervening layers may be present therebetween. Also, if (e.g., when) an element is referred to as being arranged “on” another element, it may be arranged under the other element. For example, as used herein, “on” or “over” indicates a relationship of vertical placement and may include intervening layers unless stated as “directly on.” “Under” or “below” is the converse. “Directly on” and “directly under” exclude intervening layers.

Like numerals refer to like elements throughout the disclosure, and duplicative descriptions thereof may not be provided for conciseness. In the drawings, the thickness, ratio, and dimension of components may be exaggerated or reduced for effective description of the technical content. As used herein, the term “and/or” or “or” may include any and all combinations of one or more of the associated listed items.

It will be understood that, although the terms “first,” “second,” and/or the like may be used herein to describe one or more suitable elements, these elements should not be limited by these terms. These terms are only used to distinguish one element from another element. Thus, a first element discussed herein could be termed a second element without departing from the teachings of the present disclosure. As used herein, the singular forms, “a,” “an,” and “the” are intended to include the plural forms as well, unless the context clearly indicates otherwise. Further, the use of “may” when describing embodiments of the present disclosure refers to “one or more embodiments of the present disclosure.”

Spatially relative terms, such as “below,” “lower,” “above,” “upper,” and/or the like, may be used herein for ease of description to describe one element or feature's relationship to another elements or features as shown in the drawings.

It will be further understood that the terms “comprise(s)/comprising” and/or “include(s)/including” and/or “has(have)/having”, if (e.g., when) used in this disclosure, specify the presence of stated features, numbers, steps, operations, elements, and/or components, but do not preclude the presence or addition of one or more other features, numbers, steps, operations, elements, components, and/or groups thereof. Additionally, the terms “comprise(s)/comprising,” “include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or groups thereof.

In the present disclosure, if (e.g., when) an element is referred to as being “directly connected” to another element, there are no intervening elements present between a layer, film region, or substrate and another layer, film, region, or substrate. For example, the term “directly connected” may refer to that two layers or two members are arranged without employing additional adhesive therebetween.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an electronic apparatus according to one or more embodiments of the present disclosure will be described with reference to accompanying drawings.

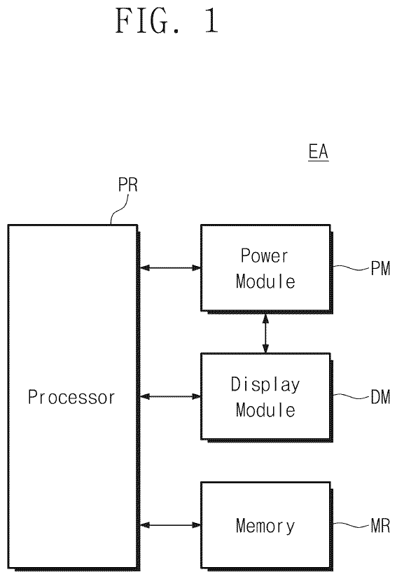

FIG. 1 is a block diagram of an electronic apparatus according to one or more embodiments of the present disclosure.

Referring to FIG. 1, an electronic apparatus EA may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), or a controller.

The memory MR may store data information desired or required for an operation of the processor PR or the display module DM. When the processor PR executes an application stored in the memory MR, an image data signal and/or an input control signal may be transmitted to the display module DM, and the display module DM may process the received signals to output image information through a display screen. The display module DM may include a display panel that displays an image.

The power module PM may include a power conversion module. The power conversion module may convert power supplied by a power supply module, such as a power adapter or a battery device, to generate power desired or required for an operation of the electronic apparatus EA.

At least one of (e.g., at least one selected from among) components of the electronic apparatus EA may be included in the display module according to one or more embodiments described later, and an electronic apparatus may include the display module according to one or more embodiments. In addition, among individual modules that are functionally included within a single module, some may be included in a display device while others may be provided separately from the display device. For example, in one or more embodiments, a display device may include the display module DM, and the processor PR, the memory MR, and the power module PM may be provided as separate devices within the electronic apparatus EA, rather than being included in the display device.

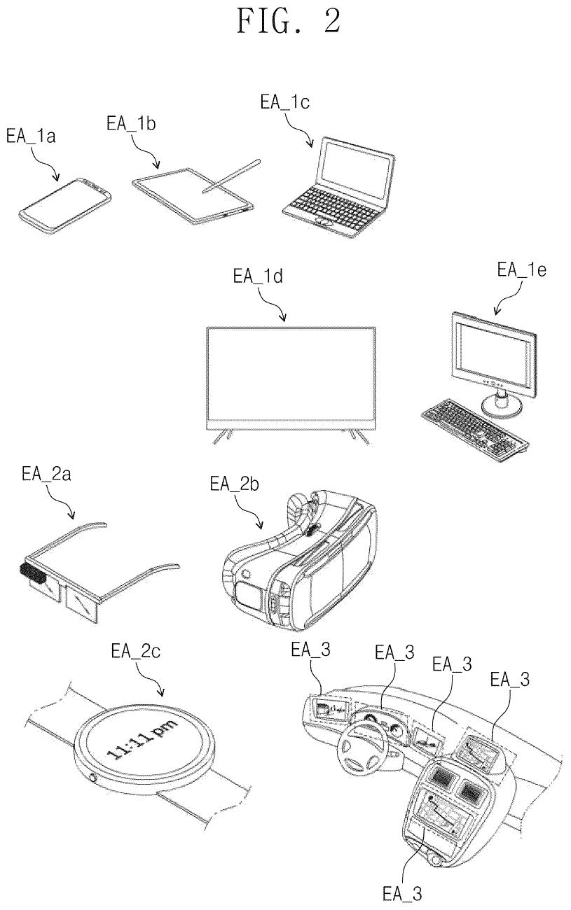

FIG. 2 is a schematic view of electronic apparatuses according to one or more embodiments of the present disclosure.

Referring to FIG. 2, one or more suitable electronic apparatuses to which the display module according to one or more embodiments is applied may include not only an electronic apparatus for displaying images, such as a smartphone EA_1a, a tablet PC EA_1b, a laptop computer EA_1c, a television EA_1d, a desktop monitor EA_1e, and/or the like, but also a wearable electronic apparatus, such as a smart glasses EA_2a, a head-mounted display EA_2b, a smartwatch EA_2c, and/or the like, and an in-vehicle electronic apparatus EA_3, such as an instrument panel, a center fascia, a dashboard-mounted center information display (CID), a room mirror display, and/or the like.

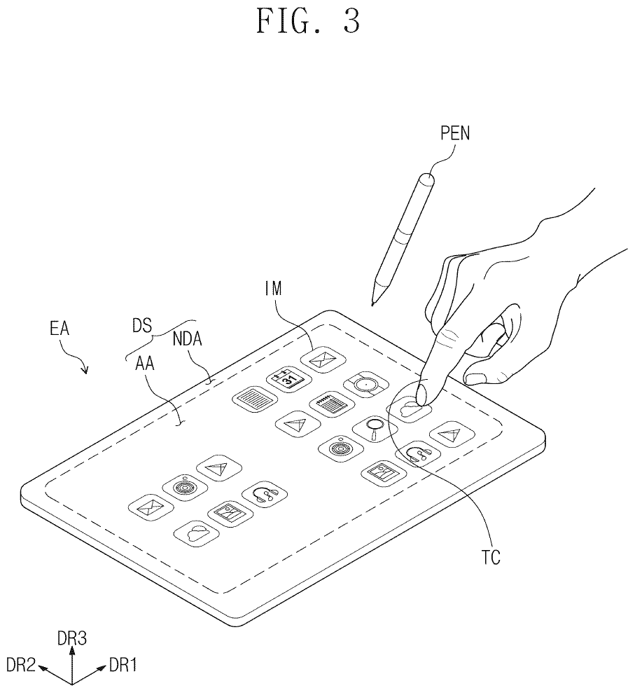

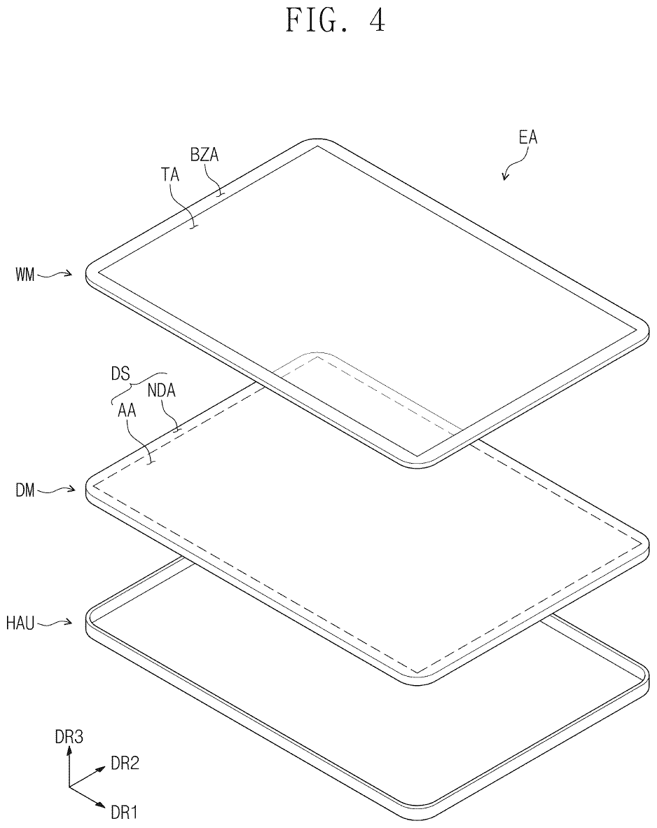

FIG. 3 is a perspective view of an electronic apparatus according to one or more embodiments of the present disclosure. FIG. 4 is an exploded perspective view of an electronic apparatus according to one or more embodiments of the present disclosure.

Referring to FIG. 3, in one or more embodiments, an electronic apparatus EA may have long sides extending parallel to a first direction DR1 and short sides extending parallel to a second direction DR2, which intersects the first direction DR1. However, this is merely an example, and the electronic apparatus EA may instead have sides of equal length in both (e.g., simultaneously) the first and second directions DR1 and DR2.

Hereinafter, a direction substantially normal (e.g., perpendicular) to a plane defined by the first direction DR1 and the second direction DR2 is referred to as a third direction DR3. In the following descriptions, the expression “if (e.g., when) viewed in a plane,” or “in plan view” may refer to a state of being viewed in the third direction DR3. The expression “viewed in a cross-section,” “viewed in cross-section,” or “in cross-section view” may refer to a state of being viewed from a side.

A front surface of the electronic apparatus EA may be defined as a display surface DS and may include a plane defined by the first direction DR1 and the second direction DR2. An image IM generated by the electronic apparatus EA may be provided to a user through the display surface DS.

Referring to FIG. 3 and FIG. 4, the display surface DS may include an active area AA and a peripheral area NDA. The active area AA may be activated in response to electrical signals. For example, the image IM may be displayed through the active area AA, and an external input TC may be sensed in the active area AA. The active area AA may overlap at least a portion of a transmission area TA. Accordingly, the user may view the image IM or may provide the external input TC through the transmission area TA. However, this is merely an example, an area where the image IM is displayed and an area where the external input TC is sensed may be separated from each other in the active area AA, and they should not be particularly limited.

Referring to FIG. 3 and FIG. 4, the peripheral area NDA may be defined adjacent to the active area AA. For example, the peripheral area NDA may surround the active area AA. A driving circuit and/or driving lines to drive the active area AA may be arranged in the peripheral area NDA. The peripheral area NDA may overlap at least a portion of a bezel area BZA, and components, which are arranged in the peripheral area NDA, may be prevented or reduced from being viewed from the outside by the bezel area BZA.

The electronic apparatus EA may sense the external input TC applied from the outside of the electronic apparatus EA. For example, the electronic apparatus EA may sense a first input generated by the external input TC and a second input generated by a touch pen PEN. The first input generated by the external input TC may include inputs of one or more suitable forms, such as a part of a user's body, light, heat, or pressure, and/or the like. The touch pen PEN may be an active pen or an electromagnetic pen, however, it should not be limited thereto or thereby. The touch pen PEN may be defined as an input device, and the active area AA may provide the user with a sensing area capable of sensing inputs in addition to displaying images.

In one or more embodiments, the electronic apparatus EA may be a large-sized electronic apparatus, such as a television set, a monitor, or an outdoor billboard, and/or the like. In one or more embodiments, the electronic apparatus EA may be a small or medium-sized electronic apparatus, such as a personal computer, a notebook computer, a personal digital assistant, a car navigation unit, a game unit, a smartphone, a tablet computer, a camera, and/or the like. However, these are merely examples, and the electronic apparatus EA may be applied to other electronic apparatuses as long as they do not depart from the concept of the present disclosure.

Referring to FIG. 4, in one or more embodiments, the electronic apparatus EA may include a window module WM, a display module DM, and a housing HAU. The window module WM and the housing HAU may be coupled to each other to provide an exterior of the electronic apparatus EA and may protect the display module DM.

The window module WM may include the transmission area TA and the bezel area BZA. The transmission area TA may be an optically transparent area. In one or more embodiments, the transmission area TA may be an area having a visible light transmittance of about 90% or higher.

The bezel area BZA may be an area having a relatively lower transmittance than that of the transmission area TA. The bezel area BZA may define a shape of the transmission area TA. The bezel area BZA may be arranged adjacent to the transmission area TA and may surround the transmission area TA. However, this is merely an example, in one or more embodiments, the bezel area BZA of the window module WM may be adjacent to only one side of the transmission area TA or may not be provided from the window module WM. In one or more embodiments, the window module WM may include at least one functional layer selected from among an anti-fingerprint layer, a hard coating layer, and an anti-reflective layer and should not be particularly limited thereto.

The display module DM may be arranged under the window module WM. The display module DM may have a configuration that substantially generates the image IM. The image IM may include a video as well as a still image. The image IM generated by the display module DM may be displayed through the display surface DS of the display module DM and may be viewed by the user through the transmission area TA.

The housing HAU may be arranged under the display module DM. The housing HAU may be coupled with the window module WM. The housing HAU and the window module WM, which are coupled to each other, may provide an inner space. The display module DM may be accommodated in the inner space.

The housing HAU may include a material with a relatively high rigidity. For example, the housing HAU may include glass, plastic (e.g., polymer material), or metal or may include a plurality of frames and/or plates formed from any combination of these materials. The housing HAU may reliably protect the components of the electronic apparatus EA accommodated in the inner space from external impacts.

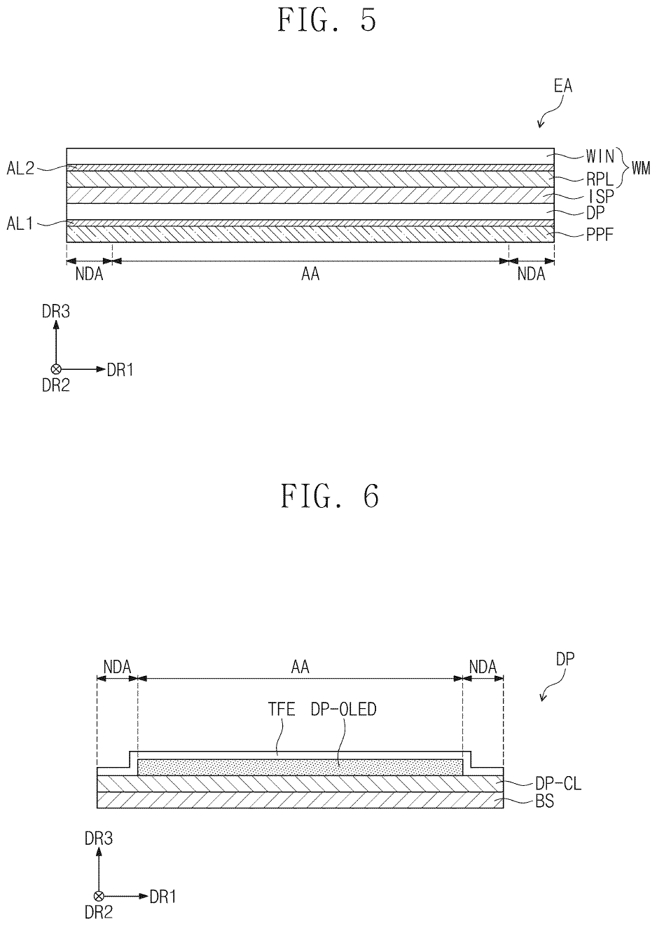

FIG. 5 is a cross-sectional view of the electronic apparatus shown in FIG. 3 according to one or more embodiments of the present disclosure. FIG. 6 is a cross-sectional view of a display panel shown in FIG. 5 according to one or more embodiments. Hereinafter, one or more embodiments of the present disclosure will be described with reference to FIG. 5 and FIG. 6.

Referring to FIG. 5, in one or more embodiments, the electronic apparatus EA may include the active area AA and the peripheral area NDA adjacent the active area AA and may include a display panel DP, an input sensing unit ISP, a window module WM, a panel protective film PPF, and first and second adhesive layers AL1 and AL2.

The display panel DP may be a light emitting type (kind) display panel. In one or more embodiments, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as a representative example of the display panel DP.

Referring to FIG. 6, the display panel DP may include a base layer BS, a circuit element layer DP-CL, a display element layer DP-OLED, and a thin film encapsulation layer TFE. The circuit element layer DP-CL, the display element layer DP-OLED, and the thin film encapsulation layer TFE may be sequentially arranged on the base layer BS, for example, in the stated order. In addition, the display panel DP may include the active area AA and the peripheral area NDA adjacent the active area AA, and the active area may be an area overlapping the display element layer DP-OLED.

The base layer BS may include a glass material or a flexible plastic material such as polyimide (PI).

A plurality of pixels may be arranged in the circuit element layer DP-CL and the display element layer DP-OLED. Each pixel may include a transistor arranged in the circuit element layer DP-CL and a light emitting element arranged in the display element layer DP-OLED and connected to the transistor.

The thin film encapsulation layer TFE may be arranged on the circuit element layer DP-CL to cover the display element layer DP-OLED. The thin film encapsulation layer TFE may protect the pixels from moisture, oxygen, and a foreign substance. In one or more embodiments, as shown in FIG. 6, the thin film encapsulation layer TFE may cover an entire area of the base layer BS; however, embodiments of the present disclosure are not limited thereto, in one or more embodiments, the base layer BS may include some areas that are exposed without being covered by the thin film encapsulation layer TFE. According to one or more embodiments, the areas exposed without being covered by the thin film encapsulation layer TFE may be formed along an edge of the base layer BS; however, embodiments of the present disclosure are not limited thereto or thereby.

Referring to FIG. 5, the input sensing unit ISP may be arranged on the display panel DP. In one or more embodiments, the input sensing unit ISP may include a plurality of sensing portions to sense an external input by a capacitive method. The input sensing unit ISP may be manufactured directly on the display panel DP when the electronic apparatus EA is manufactured. In more detail, a conductive pattern and/or an insulating layer that forms the input sensing unit ISP may be directly arranged or patterned on the display panel DP; however, embodiments of the present disclosure are not limited thereto or thereby. According to one or more embodiments, the input sensing unit ISP may be attached to the display panel DP by an adhesive layer after being manufactured separately from the display panel DP.

The window module WM may include an optical layer RPL and a window WIN. The window module WM shown in FIG. 5 may correspond to the window module WM of FIG. 4.

The optical layer RPL may be arranged on the input sensing unit ISP. The optical layer RPL may reduce a reflectance of the electronic apparatus EA with respect to an external light incident to the electronic apparatus EA from outside to improve visibility of the images displayed through the electronic apparatus EA. The optical layer RPL may include a retarder (e.g., a phase retardation layer), a polarizer, a black matrix, a color filter, and/or the like; however, embodiments of the present disclosure are not particularly limited thereto. The optical layer RPL may be formed directly on the input sensing unit ISP through a coating or deposition process or may be attached to the input sensing unit ISP by an adhesive layer after being provided as a film shape.

The window WIN may be arranged on the optical layer RPL. The window WIN may protect the display panel DP, the input sensing unit ISP, and the optical layer RPL from external scratches and impacts. The window WIN may include an optically transparent insulating material. For example, the window WIN may include a glass or plastic material.

The panel protective film PPF may be arranged under the display panel DP. The panel protective film PPF may support the display panel DP and may protect a lower portion of the display panel DP. The panel protective film PPF may have insulating properties. For example, in one or more embodiments, the panel protective film PPF may include a resin such as polyethylene terephthalate (PET), polyimide (PI), and/or polypropylene (PP); however, embodiments of the present disclosure are not limited thereto or thereby.

The first adhesive layer AL1 may be arranged between the display panel DP and the panel protective film PPF, and the display panel DP and the panel protective film PPF may be coupled to each other by the first adhesive layer AL1. The second adhesive layer AL2 may be arranged between the window WIN and the optical layer RPL, and the window WIN and the optical layer RPL may be coupled to each other by the second adhesive layer AL2.

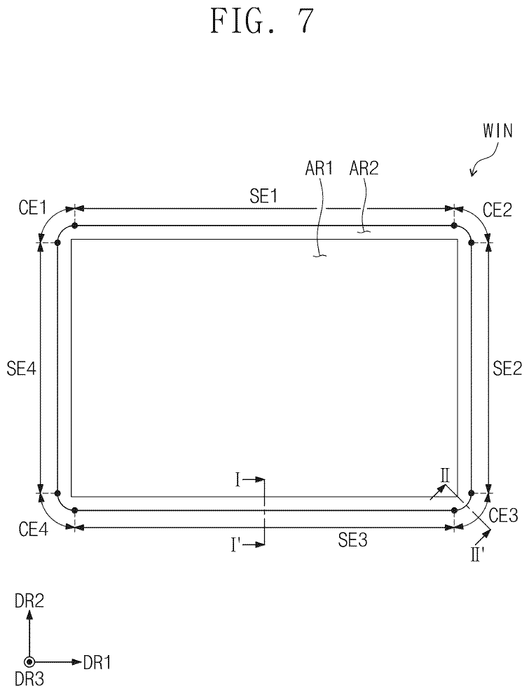

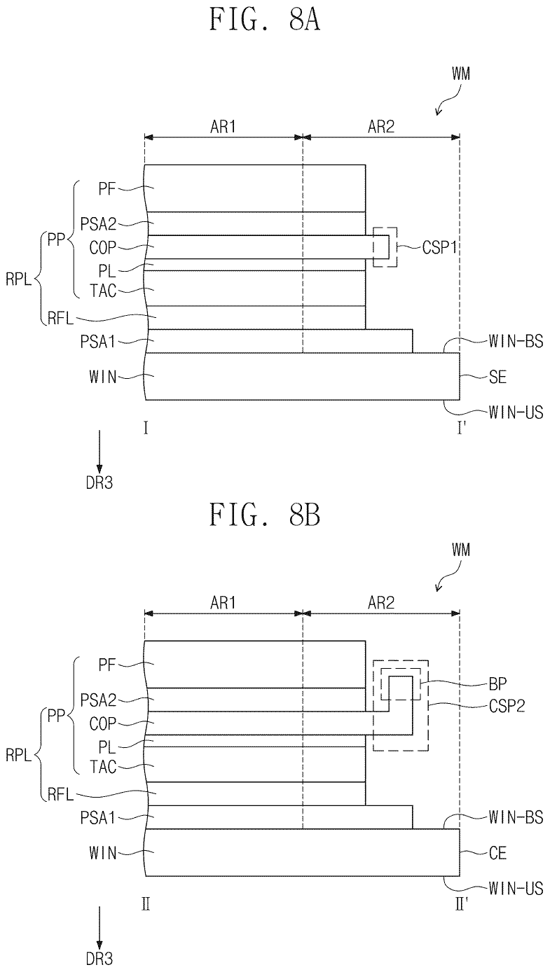

FIG. 7 is a plan view of a window according to one or more embodiments of the present disclosure. FIG. 8A is a cross-sectional view of a window module taken along the line I-I′ of FIG. 7 according to one or more embodiments of the present disclosure. FIG. 8B is a cross-sectional view of the window module taken along the line II-II′ of FIG. 7 according to one or more embodiments of the present disclosure. FIG. 8A is a cross-sectional view of a linear area of the window, and FIG. 8B is a cross-sectional view of a corner area of the window.

In the following descriptions, the corner area of the window WIN refers to an area where corner sides CE1, CE2, CE3, and CE4 of the window WIN are located if (e.g., when) viewed in a plane, i.e., in plan view, and the linear area of the window WIN refers to an area where straight sides SE1, SE2, SE3, and SE4 of the window WIN are located if (e.g., when) viewed in the plane.

Referring to FIG. 7, the window WIN may include a perimeter including four straight sides SE1, SE2, SE3, and SE4 and four corner sides CE1, CE2, CE3, and CE4 if (e.g., when) viewed in the plane (in plan view). The four corner sides CE1, CE2, CE3, and CE4 may be arranged between the straight sides SE1, SE2, SE3, and SE4, and each of the four corner sides CE1, CE2, CE3, and CE4 may connect the straight sides adjacent to each other. In other words, the corner side CE1 may be arranged between the straight side SE1 and straight side SE4 and connect the straight sides SE1 and SE4, the corner side CE2 may be arranged between the straight side SE1 and straight side SE2 and connect the straight sides SE1 and SE2, the corner side CE3 may be arranged between the straight side SE2 and straight side SE3 and connect the straight sides SE2 and SE3, the corner side CE4 may be arranged between the straight side SE3 and straight side SE4 and connect the straight sides SE3 and SE4.

The four corner sides CE1, CE2, CE3, and CE4 may have a curvature if (e.g., when) viewed in the plane. Accordingly, the perimeter of the window WIN may have a rounded shape rather than a sharp angle.

Referring to FIG. 8A and FIG. 8B, the window module WM may include the window WIN, an adhesive layer PSA1, and an optical layer RPL. For ease of explanation, FIG. 8A and FIG. 8B each illustrate a partial cross-sectional view with a rear surface WIN-BS of the window WIN oriented upward. The rear surface WIN-BS of the window WIN may be a surface opposite to (e.g., facing) the display panel DP (refer to FIG. 5), and a front surface WIN-US of the window WIN may be a surface opposite to the rear surface WIN-BS. The front surface WIN-US of the window WIN may correspond to the display surface DS (refer to FIG. 3) of the electronic apparatus EA (refer to FIG. 3). For example, the window modules WM shown in FIG. 8A and FIG. 8B may be rotated 180 degrees and then coupled to the display panel DP. Hereinafter, an upward direction refers to a direction opposite to the third direction DR3 in the descriptions of FIG. 8A and FIG. 8B.

The window WIN may include a first area AR1 and a second area AR2 around (e.g., surrounding) an edge of the first area AR1 if (e.g., when) viewed in the plane. In this regard, the first area AR1 and the second area AR2 may respectively correspond to the active area AA and the peripheral area NDA illustrated in FIG. 4 after the window module WM is coupled to the display panel DP.

The optical layer RPL may be arranged above (e.g., on) the rear surface WIN-BS of the window WIN. The optical layer RPL may include a phase retardation layer RFL and a polarizing plate PP arranged on the phase retardation layer RFL.

The phase retardation layer RFL may delay a phase of light provided from the display panel DP. In one or more embodiments, the phase retardation layer RFL may delay the phase of incident light by λ/4. The phase retardation layer RFL has an optical anisotropy and may change a polarization state of the incident light. For example, the light provided to the phase retardation layer RFL through the polarizing plate PP may be converted from a linearly polarized state to a circularly polarized state, or light provided in a circularly polarized state may be converted to a linearly polarized state.

Although FIGS. 8A and 8B each illustrate a structure in which the phase retardation layer RFL is a single layer, the embodiments of the present disclosure are not limited thereto or thereby. For example, according to one or more embodiments of the present disclosure, the phase retardation layer RFL may be formed of a plurality of layers. For instance, in one or more embodiments, the phase retardation layer RFL may have a stacked structure including a λ/4 phase retardation layer and a λ/2 phase retardation layer. In these embodiments, the λ/4 phase retardation layer RFL may convert linearly polarized light to circularly polarized light, and the λ/2 phase retardation layer may adjust a polarization direction of the circularly polarized light.

The adhesive layer PSA1 may be arranged between the window WIN and the optical layer RPL. In this regard, the adhesive layer PSA1 may correspond to the second adhesive layer AL2 illustrated in FIG. 5. The window WIN and the optical layer RPL may be attached to each other by the adhesive layer PSA1. The adhesive layer PSA1 may include a pressure sensitive adhesive (PSA).

FIG. 8A and FIG. 8B each illustrate a structure in which a side surface of the adhesive layer PSA1 is normal (e.g., perpendicular) to the rear surface WIN-BS of the window WIN as a representative example; however, this is merely an example, and embodiments of the present disclosure are not limited thereto or thereby. For example, in one or more embodiments, the side surface of the adhesive layer PSA1 may include a stepped portion with respect to a side surface of the window WIN.

The polarizing plate PP according to one or more embodiments of the present disclosure may include a plurality of layers. For example, in one or more embodiments, the polarizing plate PP may include first, second, and third layers TAC, COP, and PF and an adhesive member PSA2, which are sequentially stacked in a direction opposite to the third direction DR3. However, this is merely an example, and the number of layers constituting the polarizing plate PP may be modified in one or more suitable ways and should not be particularly limited.

The first layer TAC may be an organic layer. The first layer TAC may be a film. The first layer TAC may be optically transparent. For example, in one or more embodiments, the first layer TAC may be a triacetylcellulose layer. The first layer TAC may serve as a protective layer. The first layer TAC may protect a polarizing layer PL arranged thereon from external impacts. In one or more embodiments, an adhesive layer may additionally be arranged between the phase retardation layer RFL and the first layer TAC.

The second layer COP may be an organic layer. The second layer COP may be a film. The second layer COP may be optically transparent. The second layer COP may serve as a protective layer. For example, in one or more embodiments, the second layer COP may be a polyolefin film.

The third layer PF may be an organic layer. The third layer PF may be a film. The third layer PF may be optically transparent. The third layer PF may serve as a protective layer. The third layer PF may be arranged above (e.g., on) the second layer COP and may protect the second layer COP from external impacts or scratches. In addition, the third layer PF may prevent or reduce external light from being reflected.

In one or more embodiments of the present disclosure, the polarizing plate PP may further include the polarizing layer PL that includes a polarizer. The polarizing layer PL may be arranged between the first layer TAC and the second layer COP. The polarizing layer PL may be an optical layer that linearly polarizes incident light in a specific direction and may function as a linear polarizer. The polarizing layer PL may be formed as a film-type (kind) linear polarizer including a stretched polymer film. For example, in one or more embodiments, the stretched polymer film may be a stretched polyvinyl alcohol-based film. The polarizing layer PL may be arranged under the second layer COP and may be protected from external impacts or scratches. However, in one or more embodiments, the polarizing layer PL may not be provided.

The adhesive member PSA2 may be arranged between the second layer COP and the third layer PF. The second layer COP and the third layer PF may be coupled to each other by the adhesive member PSA2. The adhesive member PSA2 may include a pressure sensitive adhesive (PSA).

The second layer COP may have a side surface of different shapes depending on its position.

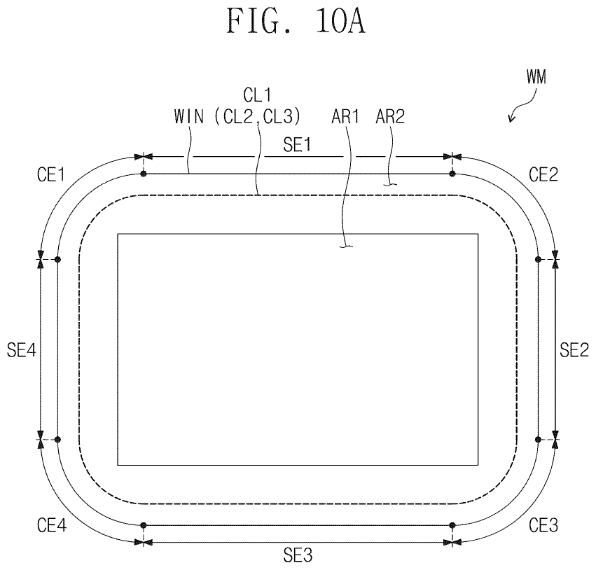

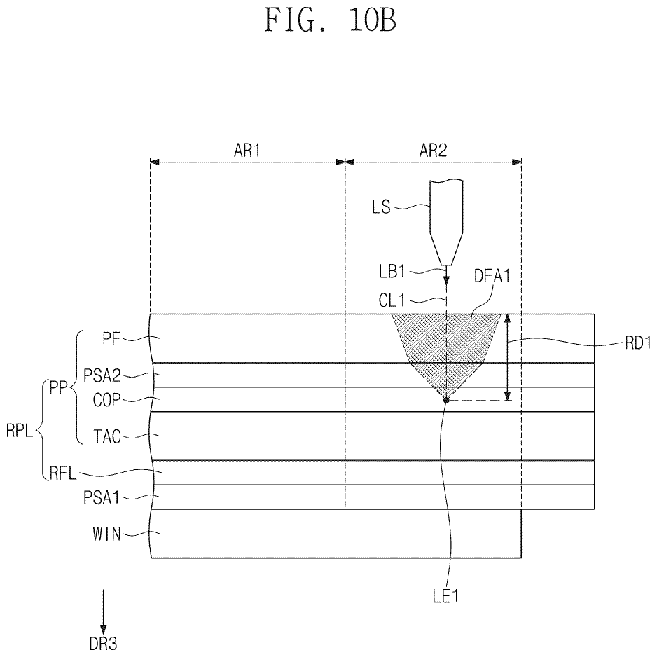

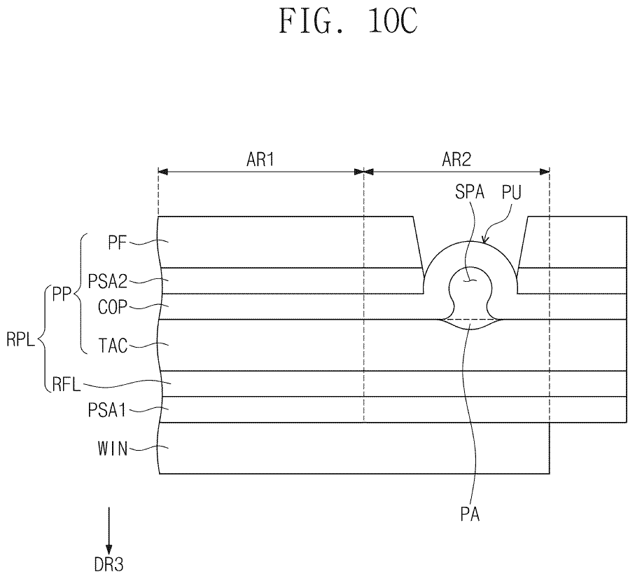

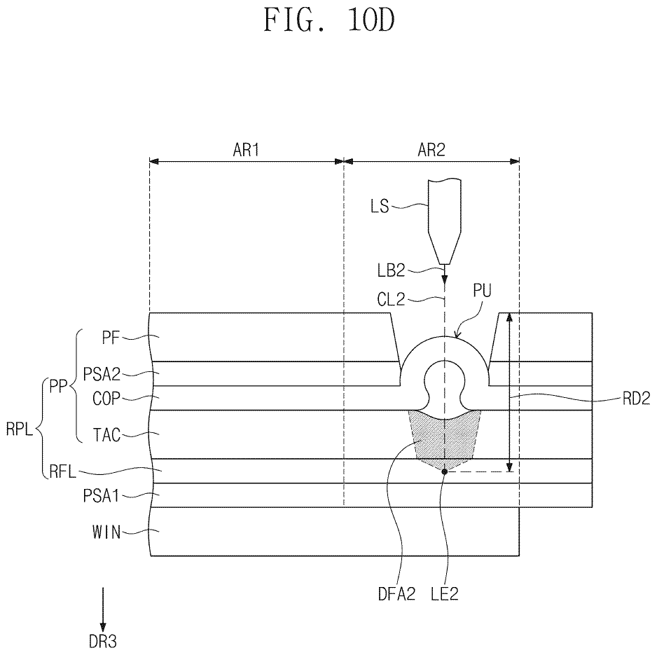

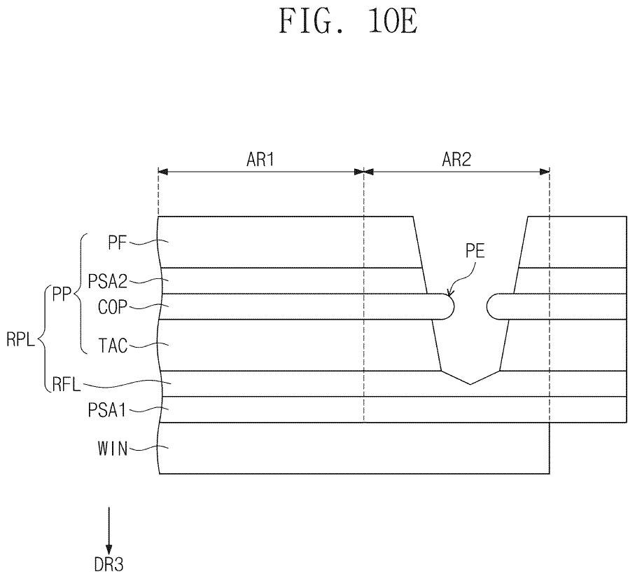

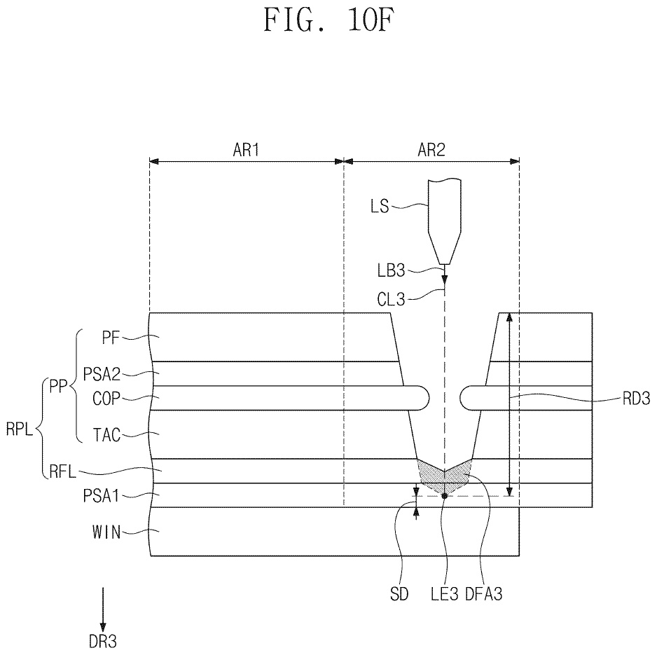

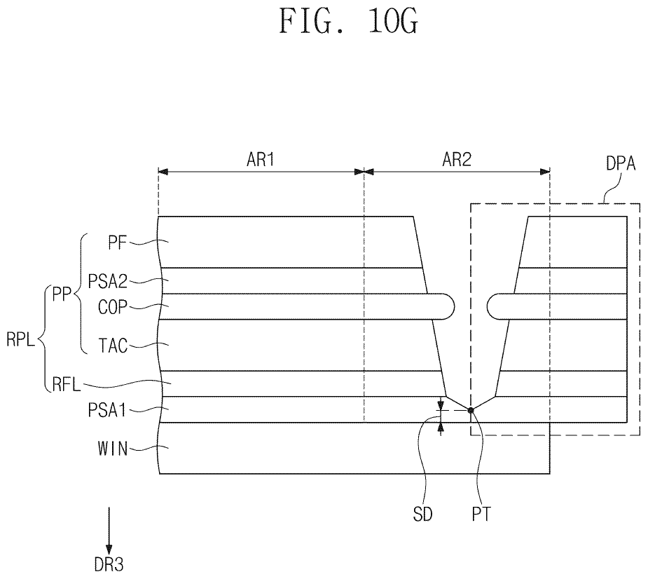

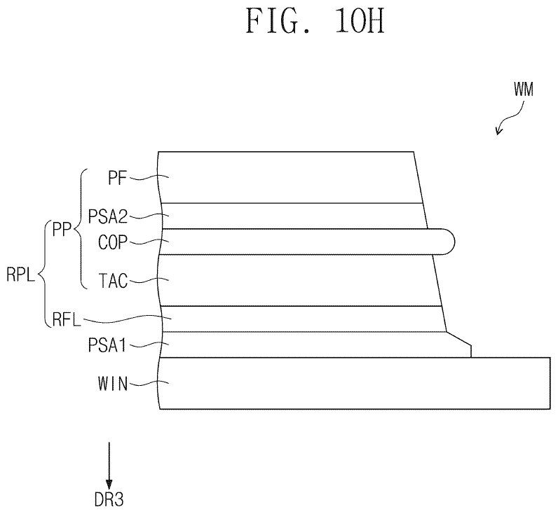

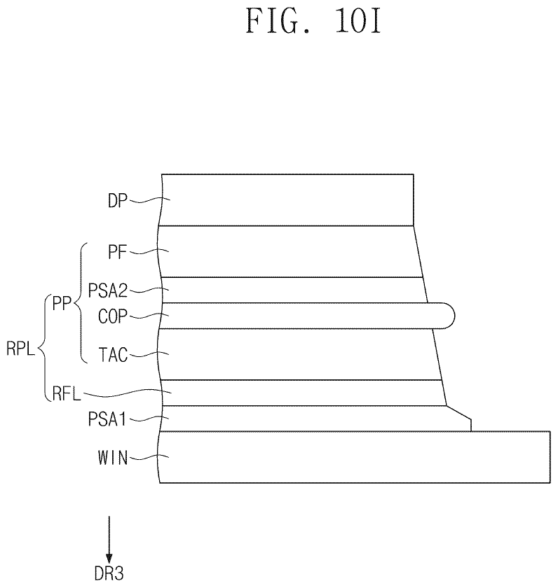

In more detail, referring to FIG. 8A, in one or more embodiments, the second layer COP may include a first side portion CSP1 that protrudes toward a straight side SE of the window WIN. For example, the first side portion CSP1 may protrude in a direction away from the first area AR1 beyond side surfaces of the first layer TAC and the third layer PF. This structure may be formed because an intensity of a laser beam irradiated in a second laser irradiation operation, which follows a first laser irradiation operation in a window module cutting process described later, is lower than an intensity of a laser beam irradiated in the first laser irradiation operation. Due to such a structure, it may facilitate focus adjustment of the laser beam and may minimize or reduce thermal influence applied to the layers arranged under the first layer TAC during a laser cutting process. Further, because a protruding portion PU (refer to FIG. 10C) is formed on a side surface of the polarizing plate PP, a dummy portion DPA (refer to FIG. 10G) may be easily removed by a mechanical method. Thus, unnecessary residue may be reduced, and cutting precision may be improved.

In addition, different from a second side portion CSP2 (refer to FIG. 8B), the first side portion CSP1 may not include (e.g., may exclude) a bent portion extending toward an upper surface of the polarizing plate PP. For example, the first side portion CSP1 may not overlap with a side surface of the third layer PF arranged on the second layer COP if (e.g., when) viewed in a cross-section.

Referring to FIG. 8B, in one or more embodiments, the second layer COP may include the second side portion CSP2 that protrudes toward a corner side CE of the window WIN. For example, the second side portion CSP2 may protrude in a direction away from the first area AR1 beyond the side surfaces of the first layer TAC and the third layer PF. The second side portion CSP2 may include a bent portion BP that is bent toward a direction opposite to the third direction DR3. In this regard, the bent portion BP may be arranged in substantially the same plane as at least a portion of the third layer PF. The bent portion BP may overlap with the peripheral area NDA if (e.g., when) viewed in the plane.

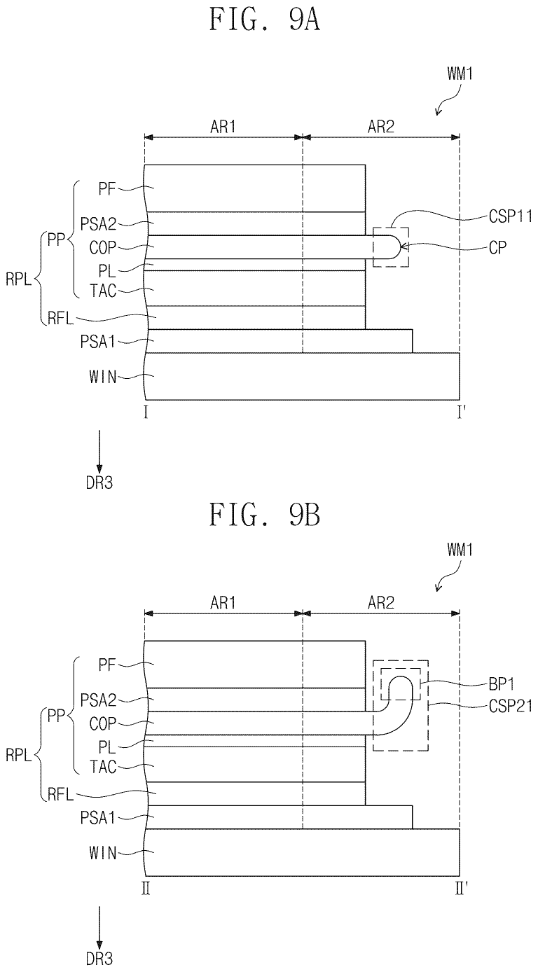

FIG. 9A is a cross-sectional view of a window module taken along the line I-I′ of FIG. 7 according to one or more embodiments of the present disclosure. FIG. 9B is a cross-sectional view of the window module taken along the line II-II′ of FIG. 7 according to one or more embodiments of the present disclosure. FIG. 9A is a cross-sectional view of a linear area of a window, and FIG. 9B is a cross-sectional view of a corner area of the window. In FIG. 9A and FIG. 9B, the same/similar reference numerals denote the same/similar elements shown in FIGS. 7, 8A, and 8B, and thus, detailed descriptions of the same/similar elements will not be provided for conciseness.

Referring to FIG. 9A, in one or more embodiments, a first side portion CSP11 of a second layer COP may include a curved surface CP. The curved surface CP may be formed when a first layer TAC arranged under the second layer COP expands due to a laser beam irradiation during a window module cutting process, which will be described later. Because the first side portion CSP11 has a curved structure, the concentration of thermal stress at specific locations during the laser cutting process may be alleviated, and thermal damage to layers arranged under the second layer COP may be reduced.

Referring to FIG. 9B, in one or more embodiments, a second side portion CSP21 may include a bent portion BP1 that is bent toward a direction opposite to the third direction DR3, and the bent portion BP1 may include a curved surface. Because the bent portion BP1 includes the curved structure, the concentration of thermal stress at specific locations during the laser cutting process may be alleviated, and thermal damage to layers arranged under the second layer COP may be reduced.

FIG. 10A is a plan view of a window module according to one or more embodiments of the present disclosure. FIGS. 10B to 10I are cross-sectional views illustrating processes of a method of manufacturing the electronic apparatus according to one or more embodiments of the present disclosure. FIGS. 10B to 10I illustrate a laser cutting process performed on the window module cut along the line I-I′ of FIG. 7 according to one or more embodiments. Hereinafter, in FIGS. 10A to 10I, the same/similar reference numerals denote the same/similar elements shown in FIGS. 7 to 9B, and thus, detailed descriptions of the same/similar elements will not be provided for conciseness.

Referring to FIGS. 10A to 10I, a window module WM may be formed by cutting a preliminary window module. The preliminary window module may have a structure in which the window WIN, the adhesive layer PSA1, and the optical layer RPL are sequentially stacked. The window WIN may include the first area AR1 and the second area AR2 that surrounds the edge of the first area AR1 if (e.g., when) viewed in the plane. In the presented embodiments, for ease of explanation, the edge of each of the first area AR1 and the second area AR2 is illustrated with a solid line. The preliminary window module may be cut using a laser beam. The operation of cutting the preliminary window module may include a first irradiation operation, a second irradiation operation, and a third irradiation operation. In the presented embodiments, for convenience of explanation, imaginary irradiation lines CL1, CL2, and/or CL3 are each depicted as a dotted line. In addition, FIG. 10A schematically illustrates positions and shapes of first to third irradiation lines, and the spacing relationships between the irradiation lines are not illustrated.

FIG. 10B illustrates the first irradiation operation that irradiates a first laser beam LB1 to the preliminary window module.

Referring to FIG. 10A and FIG. 10B, the first laser beam LB1 may be irradiated along a first irradiation line CL1 from a laser irradiation unit LS. The first irradiation line CL1 may be defined along the second area AR2, and the first laser beam LB1 may be irradiated along the second area AR2, while being spaced and/or apart (e.g., spaced apart or separated) from the first area AR1. Portions of the first irradiation line CL1, which are adjacent to the corner sides CE1, CE2, CE3, and CE4 of the window if (e.g., when) viewed in the plane, may have a curvature. However, a shape of the first irradiation line CL1 are not limited thereto or thereby and may be modified in one or more suitable ways.

A first depth RD1 reached by the first laser beam LB1 may be greater than a distance from an upper surface of the optical layer RPL to an upper surface of the second layer COP. In this regard, the first depth RD1 may refer to a distance from the upper surface of the optical layer RPL to an end LE1 of the first irradiation line CL1 (e.g., in the third direction DR3). In more detail, the first laser beam LB1 may reach from the upper surface of the optical layer RPL into an interior of the second layer COP to the first depth RD1 after passing through the upper surface of the second layer COP. The first depth RD1 may be a depth at which at least the second layer COP is not penetrated.

When the first laser beam LB1 is irradiated onto the preliminary window module, deformation may occur in an area (hereinafter, referred to as a first deformed area DFA1) of the preliminary window module where the first laser beam LB1 is absorbed. In FIG. 10B, for convenience of explanation, the first deformed area DFA1 is shown shaded. The deformation caused by the first laser beam LB1 may include a state change such as melting. In this regard, the first deformed area DFA1 may have a width that decreases in a thickness direction as a distance from the laser irradiation unit LS increases when viewed in the cross-section. In the preliminary window module, the deformation may occur most widely in a portion where the first laser beam LB1 is first incident and thus exposed for a longer time/period, and the deformation may occur most narrowly in a portion where the first laser beam LB1 arrives last and thus is exposed for a relatively shorter time/period. Accordingly, the first deformed area DFA1 may have a reverse tapered shape if (e.g., when) viewed in the cross-section. A width of the first deformed area DFA1 in the cross-section may vary along the thickness direction. However, a shape of the first deformed area DFA1 are not limited thereto or thereby.

Referring to FIG. 10B and FIG. 10C, the first deformed area DFA1 may be removed through the first irradiation operation performed on the preliminary window module.

In addition, during the first irradiation operation, because the second layer COP has a relatively high transmittance, a residual energy of the first laser beam LB1 may be absorbed by the first layer TAC even though the first laser beam LB1 does not directly reach the first layer TAC, and a partial area PA of the first layer TAC may be vaporized. An internal pressure between the first layer TAC and the second layer COP may locally increase due to gas (or gaseous substance) generated by the vaporization of the partial area PA of the first layer TAC, and thus deformation such as expansion of a portion of the first layer TAC may occur. Accordingly, a curved portion PU may be formed in the first layer TAC, and an empty space SPA may be formed between the first layer TAC and the second layer COP. The size and shape of the curved portion PU may vary depending on the irradiation conditions of the first laser beam LB1 and the physical properties of the first layer TAC and the second layer COP.

FIG. 10D illustrates the second irradiation operation that irradiates a second laser beam LB2 onto the preliminary window module.

Referring to FIG. 10A and FIG. 10D, the second laser beam LB2 may be irradiated along a second irradiation line CL2 from the laser irradiation unit LS. The second irradiation line CL2 may be defined along the second area AR2, and the second laser beam LB2 may be irradiated along the second area AR2, while being spaced and/or apart (e.g., spaced apart or separated) from the first area AR1. Portions of the second irradiation line CL2, which are adjacent to the corner sides CE1, CE2, CE3, and CE4 of the window when viewed in the plane, may have a curvature. However, a shape of the second irradiation line CL2 are not limited thereto or thereby and may be modified in one or more suitable ways.

A second depth RD2 reached by the second laser beam LB2 may be greater than a distance from the upper surface of the optical layer RPL to an upper surface of the phase retardation layer RFL. In this regard, the second depth RD2 may refer to a distance from the upper surface of the optical layer RPL to an end LE2 of the second irradiation line CL2 (e.g., in the third direction DR3). In more detail, the second laser beam LB2 may reach from the upper surface of the optical layer RPL into an interior of the phase retardation layer RFL to the second depth RD2 after passing through the upper surface of the phase retardation layer RFL. The second depth RD2 may be a depth that, at least, does not reach the adhesive layer PSA1.

When the second laser beam LB2 is irradiated onto the preliminary window module, deformation may occur in an area (hereinafter, referred to as a second deformed area DFA2) of the preliminary window module where the second laser beam LB2 is absorbed. In FIG. 10D, for convenience of explanation, the second deformed area DFA2 is shown shaded. The deformation caused by the second laser beam LB2 may include a state change such as melting. In the presented embodiments, the second deformed area DFA2 may be formed with a shape extending from the removed first deformed area DFA1. However, this is merely an example, and the second deformed area DFA2 may have one or more suitable shapes depending on the irradiation conditions of the second laser beam LB2 and is not particularly limited.

The second deformed area DFA2 may have a width that decreases in the thickness direction as a distance from the laser irradiation unit LS increases if (e.g., when) viewed in the cross-section. Accordingly, the second deformed area DFA2 may have a shape that narrows downward in the cross-section. In addition, a width of the second deformed area DFA2 in the cross-section may vary along the thickness direction. However, a shape of the second deformed area DFA2 is not limited thereto or thereby.

The second irradiation operation may be performed after the first irradiation operation. The first laser beam LB1 and the second laser beam LB2 may be laser beams irradiated from the same laser irradiation unit LS. After one portion of the preliminary window module is cut by irradiating the first laser beam LB1, another portion of the preliminary window module may be cut by irradiating the second laser beam LB2. In this regard, a power of the second laser beam LB2 may be less than a power of the first laser beam LB1. When the power of the second laser beam LB2 is set to be less than that of the first laser beam LB1, impact applied to the layers of the optical layer RPL, which are relatively close to the window WIN, may be reduced.

Referring to FIG. 10D and FIG. 10E, the second deformed area DFA2 may be removed through the second irradiation operation performed on the preliminary window module. After the second irradiation operation, an end PE of the processed area of the second layer COP may be formed with a curved surface. As heat generated by the second laser beam LB2 is locally applied to the curved portion PU formed in the second layer COP as described above, melting or vaporization may occur, resulting in cutting. As a result, the end PE of the finally processed area may have the curved surface.

Referring to FIG. 10A and FIG. 10F, a third laser beam LB3 may be irradiated along a third irradiation line CL3 from the laser irradiation unit LS. The third irradiation line CL3 may be defined along the second area AR2, and the third laser beam LB3 may be irradiated along the second area AR2, while being spaced and/or apart (e.g., spaced apart and/or separated) from the first area AR1. Portions of the third irradiation line CL3, which are adjacent to the corner sides CE1, CE2, CE3, and CE4 of the window when viewed in the plane, may have a curvature. However, a shape of the third irradiation line CL3 is not limited thereto or thereby and may be modified in one or more suitable ways.

A third depth RD3 reached by the third laser beam LB3 may be smaller than a distance from the upper surface of the optical layer RPL to a lower surface of the adhesive layer PSA1. In this regard, the third depth RD3 may refer to a distance from the upper surface of the optical layer RPL to an end LE3 of the third irradiation line CL3 (e.g., in the third direction DR3). In more detail, the third laser beam LB3 may reach into an interior of the adhesive layer PSA1 to the third depth RD3 after passing through the upper surface of the adhesive layer PSA1. The third depth RD3 may be a depth that, at least, does not reach the window WIN.

When the third laser beam LB3 is irradiated onto the preliminary window module, deformation may occur in an area (hereinafter, referred to as a third deformed area DFA3) of the preliminary window module where the third laser beam LB3 is absorbed. In FIG. 10F, for convenience of explanation, the third deformed area DFA3 is shown shaded. The deformation caused by the third laser beam LB3 may include a state change such as melting. In the presented embodiments, the third deformed area DFA3 may be formed with a shape extending from the removed second deformed area DFA2. However, this is merely an example, and the third deformed area DFA3 may have one or more suitable shapes depending on the irradiation conditions of the third laser beam LB3 and is not particularly limited.

The third deformed area DFA3 may have a width that decreases in the thickness direction as a distance from the laser irradiation unit LS increases if (e.g., when) viewed in the cross-section. Accordingly, the third deformed area DFA3 may have a shape that narrows downward in the cross-section. In addition, a width of the third deformed area DFA3 in the cross-section may vary along the thickness direction. However, a shape of the third deformed area DFA3 is not limited thereto or thereby.

The third irradiation operation may be performed after the second irradiation operation. The first, second, and third laser beams LB1, LB2, and LB3 may be laser beams irradiated from the same laser irradiation unit LS. After cutting portions of the preliminary window module by irradiating the first laser beam LB1 and the second laser beam LB2, another portion of the preliminary window module may be cut. In this regard, a power of the third laser beam LB3 may be less than the power of each of the first and second laser beams LB1 and LB2. In the third irradiation operation, the power of the third laser beam LB3 may be set to be less than that of each of the first and second laser beams LB1 and LB2 and may be precisely controlled or selected to minimize or reduce a residual thickness SD of the adhesive layer PSA1 that overlaps with the third irradiation line CL3. Thus, impact applied to the window WIN when removing a dummy portion DPA (see FIG. 10F) may be reduced.

Referring to FIG. 10F and FIG. 10G, when the third irradiation operation for the preliminary window module is completed, the third deformed area DFA3 may be removed. After the third deformed area DFA3 is removed, the residual thickness SD of the adhesive layer PSA1 may be about 20 micrometers or less. If (e.g., when) the residual thickness SD of the adhesive layer PSA1 exceeds about 20 micrometers, cracks may occur due to an impact on the polarizing plate PP arranged above the adhesive layer PSA1 if (e.g., when) the dummy portion DPA is removed.

The dummy portion DPA of the window module may be removed, and thus, the window module WM illustrated in FIG. 10H may be formed. In this regard, the dummy portion DPA may be a portion spaced and/or apart (e.g., spaced apart or separated) in a direction away from the first area AR1 based on a point PT where the residual thickness SD of the adhesive layer PSA1 is minimal. The window module WM illustrated in FIG. 10H may correspond to the window module described with reference to FIG. 9A and FIG. 9B.

According to one or more embodiments of the present disclosure, as the laser beam whose power is gradually decreased is irradiated multiple times at the same location, the power of the laser beam may be easily controlled or selected. Therefore, the impact applied to the polarizing plate PP during the process of removing the dummy portion DPA may be reduced, and influence on the window WIN during the laser beam irradiation may be effectively controlled or selected. For example, the impact applied to the polarizing plate PP and the window WIN may be reduced, and damage to the window WIN may be minimized or reduced or prevented.

FIGS. 10A to 10H illustrate that the number of laser beam irradiations used to cut a specific point of the window module is three as a representative example; however, embodiments of the present disclosure are not limited thereto or thereby, and the number of laser beam irradiations may vary. In addition, the power, speed, focus, and diameter of the first, second, and third laser beams LB1, LB2, and LB3 may be differently set depending on materials of the layers constituting the window module, the cutting shape of the window module, and the material of the polarizing plate PP.

Referring to FIG. 10I, the window module WM illustrated in FIG. 10H may be bonded to the display panel DP. After the display panel DP is arranged on the polarizing plate PP, the window module WM and the display panel DP may be bonded to each other. The window module WM and the display panel DP may be bonded to each other by applying pressure. The first area AR1 and the second area AR2 may correspond to the active area AA (refer to FIG. 4) and the peripheral area NDA (refer to FIG. 4), respectively.

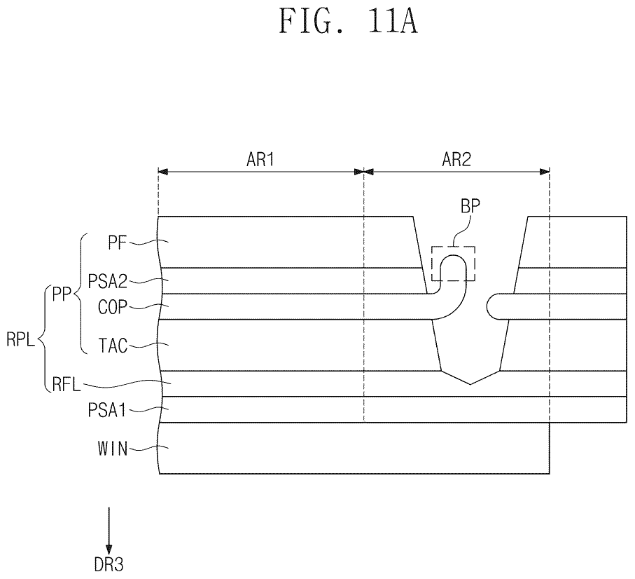

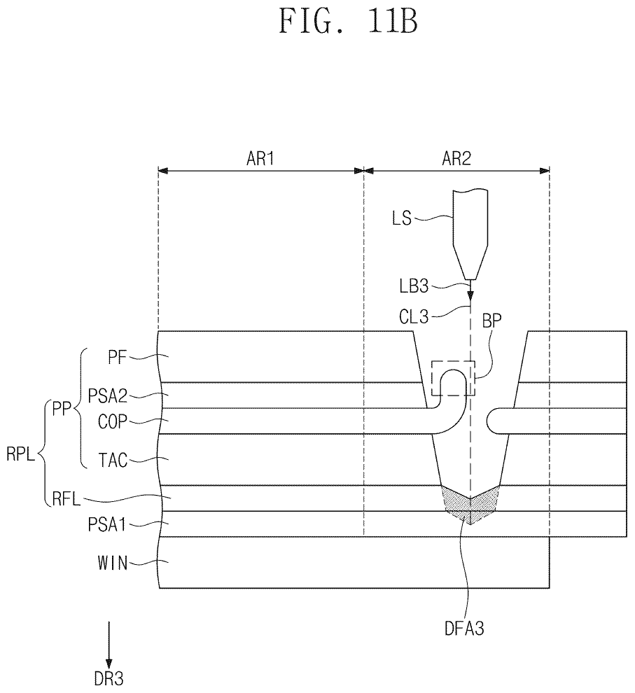

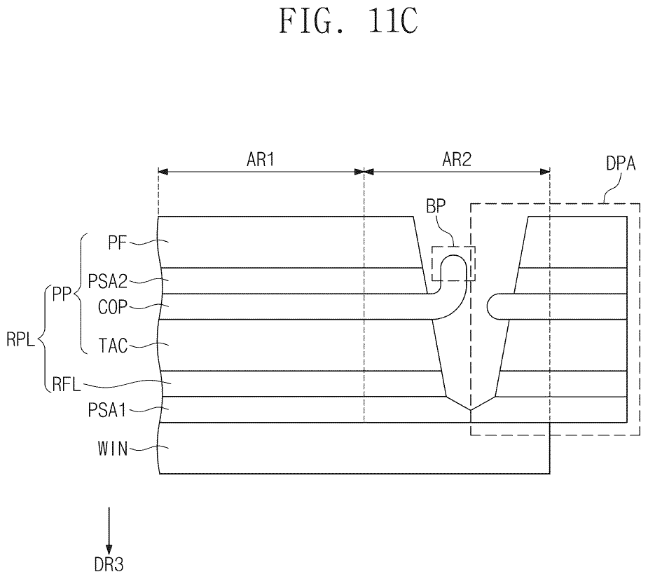

FIGS. 11A to 11C are cross-sectional views illustrating processes of the method of manufacturing an electronic apparatus according to one or more embodiments of the present disclosure. FIGS. 11A to 11C illustrate a laser cutting process performed on the window module cut along the line II-II′ of FIG. 7 according to one or more embodiments. Hereinafter, in FIGS. 11A to 11C, the same/similar reference numerals denote the same/similar elements shown in FIGS. 7 to 10H, and thus, detailed descriptions of the same/similar elements will not be provided for conciseness.

FIG. 11A illustrates a cross-section of the window module in the corner area after the second irradiation operation. Referring to FIG. 11A, after the second irradiation operation, the end of the processed area of the second layer COP may be formed with a curved surface. In addition, the bent portion BP bent toward the direction opposite to the third direction DR3 may be formed at the end of the processed area of the second layer COP. This structure may be formed by setting at least one irradiation line among the irradiation lines to be spaced and/or apart (e.g., spaced apart or separated) from the other irradiation lines when cutting the corner area of the window module. Further, when at least one irradiation line among the irradiation lines is shifted, the power of the laser beam may be dispersed, and thus the structure including the bent portion BP may be formed unlike the embodiments in which the laser beam is irradiated multiple times at the same location. In this regard, the bent portion BP may have the curved surface. Detailed descriptions related to the spacing of the irradiation lines in the corner area of the window module will be described later.

Referring to FIG. 11B and FIG. 11C, the third deformed area DFA3 where the third laser beam LB3 is absorbed may be removed. In this regard, the curved structure including the bent portion BP may alleviate the concentration of thermal stress at the specific location during the laser cutting process, and the thermal damage to the layers arranged under the second layer COP may be reduced.

The dummy portion DPA of the window module illustrated FIG. 11C may be removed. The bent portion BP of the second layer COP described above may remain even after the removal of the dummy portion DPA. For example, according to one or more embodiments of the present disclosure, after the removal of the dummy portion DPA, the shape of the side surface of the second layer COP adjacent to the corner area of the window WIN may be different from the shape of the side surface adjacent to the linear area of the window WIN. The window module formed after the removal of the dummy portion DPA may correspond to the window module WM1 described with reference to FIG. 9A and FIG. 9B.

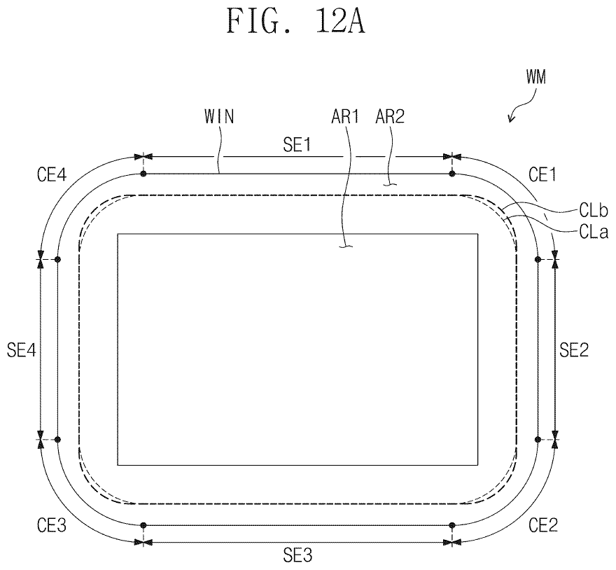

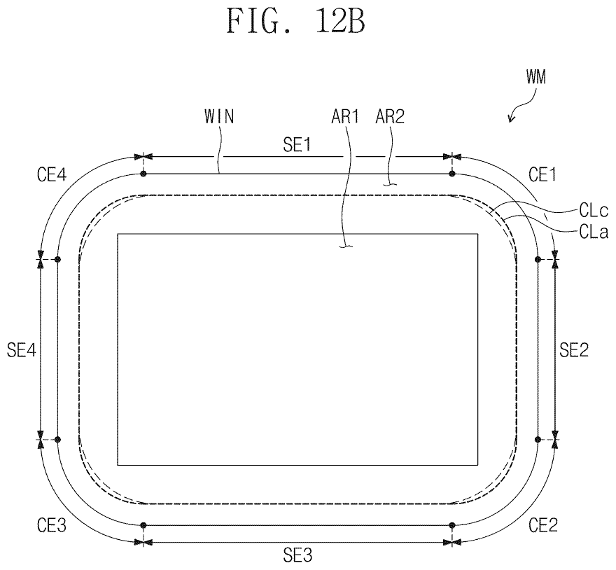

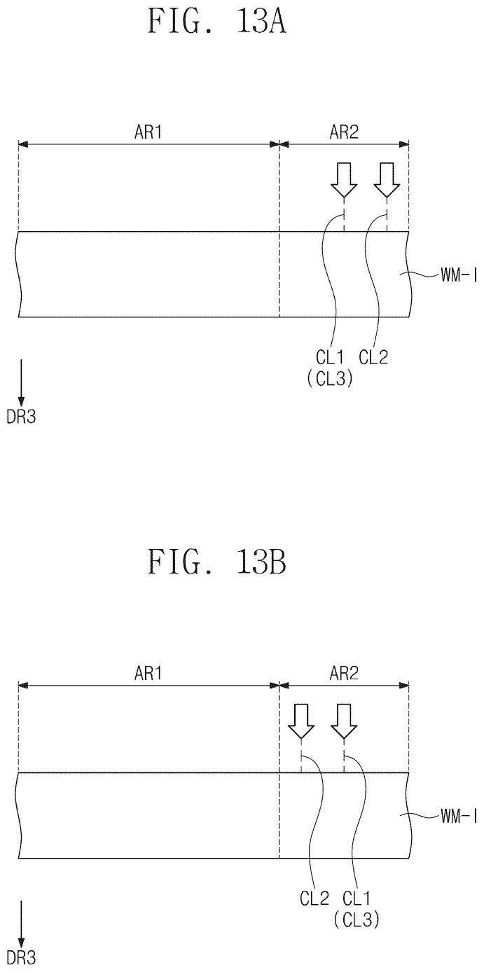

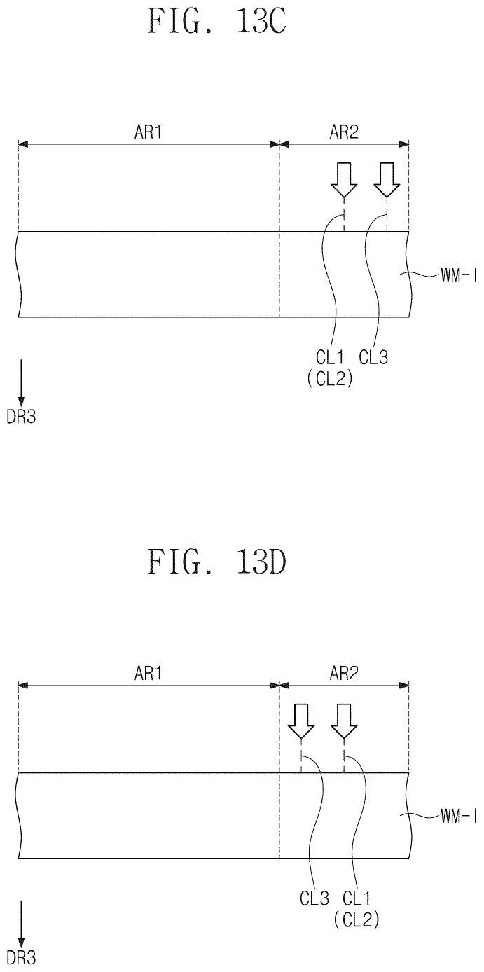

FIG. 12A and FIG. 12B are each a plan view of a window module according to one or more embodiments of the present disclosure. FIGS. 13A to 13D are schematic views illustrating a spacing relationship between irradiation lines according to one or more embodiments of the present disclosure. In FIG. 12A and FIG. 12B, for convenience of explanation, each virtual irradiation line CL is illustrated as a dotted line, and FIGS. 13A to 13D each illustrate a cross-sectional view of a preliminary window module WM-I in a corner area. First, second, and third irradiation lines CL1, CL2, and CL3 illustrated in FIGS. 13A to 13D may respectively correspond to the first, second, and third irradiation lines CL1, CL2, and CL3 described with reference to FIGS. 10A to 11C.

Referring to FIG. 12A, in one or more embodiments, a window WIN may have edges including four straight sides SE1, SE2, SE3, and SE4 and four corner sides CE1, CE2, CE3, and CE4 that are arranged between the straight sides SE1, SE2, SE3, and SE4 to connect the straight sides adjacent to each other among the straight sides SE1, SE2, SE3, and SE4 if (e.g., when) viewed in the plane (in plan view). Each of irradiation lines CLa and CLb may have a curvature in areas adjacent to the corner sides CE1, CE2, CE3, and CE4 of the window WIN.

In one or more embodiments, a specific irradiation line CLb may include a portion spaced and/or apart (e.g., spaced apart or separated) from a first irradiation line CLa if (e.g., when) viewed in the plane. For example, the specific irradiation line CLb may be set at a position different from that of the first irradiation line CLa in the corner area.

For example, in one or more embodiments, the specific irradiation line CLb may be provided at a position overlapping with the first irradiation line CLa in areas adjacent to the straight sides SE1, SE2, SE3, and SE4 of the window WIN if (e.g., when) viewed in the plane and may be provided at a position not overlapping with the first irradiation line CLa in areas adjacent to the corner sides CE1, CE2, CE3, and CE4 of the window WIN.

For example, in one or more embodiments, the specific irradiation line CLb may be set to be located in a direction away from the first area AR1 relative to the first irradiation line CLa. If (e.g., when) at least one of the irradiation lines is shifted, the power of the laser beam may be dispersed. In the corner area of the window WIN, the degree of overlap of the laser beam in a specific area may increase compared to the linear areas. Further, if (e.g., when) a polyvinyl alcohol-based film is additionally arranged between a triacetylcellulose layer and a polyolefin film, quality degradation of the window may occur in the corner area of the window WIN due to differences in the shrinkage degree of the films. According to one or more embodiments of the present disclosure, because at least one of the irradiation lines is shifted, impact applied to an optical layer RPL adjacent to the corner area of the window WIN may be reduced compared to the case where the laser beam is irradiated multiple times at the same location.

Referring to FIG. 12B, in one or more embodiments, a specific irradiation line CLc may be spaced and/or apart (e.g., spaced apart or separated) from a first irradiation line CLa in an area adjacent to a corner area of a window WIN if (e.g., when) viewed in the plane. In these embodiments, unlike in FIG. 12A, the specific irradiation line CLc may be set to be located in a direction approaching the first area AR1 relative to the first irradiation line CLa. Even in this configuration, the power of the laser beam may be dispersed, and thus, impact applied to an optical layer RPL adjacent to the corner area of the window WIN may be reduced compared to the case in which the laser beam is irradiated at the same location multiple times.

In the presented embodiments, the first irradiation line CLa may correspond to the first irradiation line CL1 described with reference to FIG. 10A to 11C, and the specific irradiation lines CLb and CLc may correspond to the second irradiation line CL2 or the third irradiation line CL3.

Referring to FIG. 13A, in one or more embodiments, in the corner area of the window WIN, the second irradiation line CL2 may be located farther from the first area AR1 than the first irradiation line CL1 is, and the third irradiation line CL3 may coincide with the first irradiation line CL1. For example, in the corner area of the window WIN, the first laser beam LB1 (refer to FIG. 10B) and the third laser beam LB3 (refer to FIG. 10F) may be irradiated at a same location during the first and third irradiation operations while the second laser beam LB2 (refer to FIG. 10D) may be irradiated at a location different from that of the first and third irradiation operations during the second irradiation operation.

Referring to FIG. 13B, in one or more embodiments, in the corner area of the window WIN, the second irradiation line CL2 may be located closer to the first area AR1 than the first irradiation line CL1 is, and the third irradiation line CL3 may coincide with the first irradiation line CL1. For example, in the corner area of the window WIN, the first laser beam LB1 and the third laser beam LB3 may be irradiated at a same location during the first and third irradiation operations while the second laser beam LB2 may be irradiated at a location different from that of the first and third irradiation operations during the second irradiation operation.

Referring to FIG. 13C, in one or more embodiments, in the corner area of the window WIN, the third irradiation line CL3 may be located farther from the first area AR1 than the first irradiation line CL1 is, and the second irradiation line CL2 may coincide with the first irradiation line CL1. For example, in the corner area of the window WIN, the first laser beam LB1 and the second laser beam LB2 may be irradiated at a same location during the first and second irradiation operations while the third laser beam LB3 may be irradiated at a location different from that of the first and second irradiation operations during the third irradiation operation.

Referring to FIG. 13D, in one or more embodiments, in the corner area of the window WIN, the third irradiation line CL3 may be located closer to the first area AR1 than the first irradiation line CL1 is, and the second irradiation line CL2 may coincide with the first irradiation line CL1. For example, in the corner area of the window WIN, the first laser beam LB1 and the second laser beam LB2 may be irradiated at a same location during the first and second irradiation operations while the third laser beam LB3 may be irradiated at a location different from that of the first and second irradiation operations.

FIGS. 13A to 13D illustrate that the second and third irradiation lines CL2 and CL3 are independently located closer to or farther from the first area AR1 relative to the first irradiation line CL1; however, embodiments of the present disclosure are not limited thereto or thereby. As long as the power of the laser beam is effectively dispersed, one or more suitable modifications may be made, such as shifting the positions of two or more laser beams or changing the arrangement of two or more laser beams, and embodiments of the present disclosure are not particularly limited thereto.

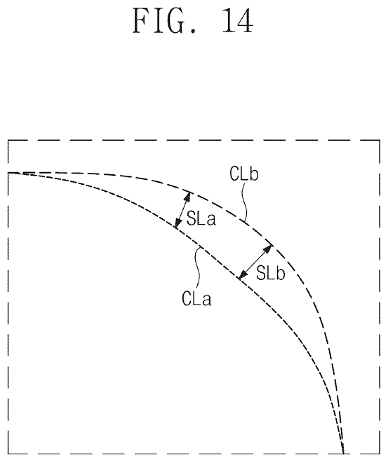

FIG. 14 is a schematic view illustrating a separation distance of the irradiation lines in the corner area of the window according to one or more embodiments of the present disclosure.

Referring to FIG. 14, as described above, the specific irradiation line CLb may be spaced apart from the first irradiation line CLa in the corner area of the window WIN if (e.g., when) viewed in the plane. The first irradiation line CLa and the specific irradiation line CLb illustrated in FIG. 14 may correspond to the irradiation lines CLa and CLb illustrated in FIG. 12A, respectively. In this regard, separation distances SLa and SLb from the first irradiation line CLa to the specific irradiation line CLb may vary depending on the curvature of each of the adjacent corner sides CE1, CE2, CE3, and CE4 (refer to FIG. 12A). For example, in one or more embodiments, the separation distances SLa and SLb between the first irradiation line CLa and the specific irradiation line CLb may be locally changed according to differences in curvature at various positions within the corner area of the window WIN. In the areas where the curvature is relatively large, the separation distance SLa may increase, and, conversely, in the areas where the curvature is small, the separation distance SLb may decrease. As described above, because the separation distance is differently set in accordance with the curvature of the corner area, the energy of the laser beam may be more uniformly dispersed, and the thermal stress concentrated in the specific areas due to the laser cutting process may be alleviated.

According to one or more embodiments of the present disclosure, when processing a corner portion of the preliminary window module, the power of the laser beam may be effectively dispersed by spacing at least one of the irradiation lines apart from another irradiation line. Accordingly, the processing difference between the linear area and the corner area of the window WIN may be reduced, and processing precision may be improved through more uniform cutting. For example, the disclosed embodiments integrate structural design and process control to achieve enhanced reliability and optical quality. By coordinating the geometry of the polarizing plate—including side portions of different shapes in linear and corner regions—with a multi-step laser cutting process that employs decreasing power levels and positional offsets, the apparatus minimizes or reduces thermal stress, reduces cracking risk, and improves cutting precision. These combined features enable uniform edge quality, maintain adhesive integrity, and enhance overall durability of the electronic apparatus.

In the present disclosure, expressions such as “at least one of,” “one of,” and “selected from,” when preceding a list of elements, modify the entire list of elements and do not modify the individual elements of the list. For example, “at least one of a, b, and c,” “at least one of a, b, or c,” “at least one selected from a, b, and c,” “at least one selected from among a to c,” etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The window-manufacturing apparatus, the light emitting element, the display module, the display device, the electronic devices/apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although one or more embodiments of the present disclosure have been described, it is understood that the present disclosure should not be limited to these embodiments, but one or more suitable changes and modifications may be made by one ordinary skilled in the art within the spirit and scope of the present disclosure as hereinafter claimed. Therefore, the disclosed subject matter should not be limited to any single embodiment described herein, and the scope of the present disclosure shall be determined according to the attached claims and equivalents thereof.

What is claimed is:

1. An electronic apparatus, comprising:
a display panel comprising an active area and a peripheral area adjacent to the active area;
a window on the display panel and comprising a perimeter comprising four straight sides and four corner sides arranged between the straight sides and connecting the straight sides adjacent to each other in plan view;
a housing under the display panel and accommodating the display panel;
a phase retardation layer on the window;
a polarizing plate on the phase retardation layer and comprising a plurality of layers; and
an adhesive layer between the window and the phase retardation layer to bond the window to the phase retardation layer,
wherein,
the plurality of the layers comprise a first layer, a second layer on the first layer, and a third layer on the second layer,
a side surface of the second layer comprises a first side portion adjacent to the straight sides and a second side portion adjacent to the corner sides in plan view, and
the first side portion differs in shape from the second side portion.

2. The electronic apparatus of claim 1, wherein the side surface of the second layer protrudes in a direction away from the active area beyond a side surface of the first layer and a side surface of the third layer.

3. The electronic apparatus of claim 1, wherein the side surface of the second layer has a curved surface.

4. The electronic apparatus of claim 1, wherein the second side portion comprises a bent portion bent toward the third layer.

5. The electronic apparatus of claim 4, wherein the bent portion is at a same plane as at least a portion of the third layer.

6. The electronic apparatus of claim 4, wherein an end of the bent portion comprises a curved surface.

7. The electronic apparatus of claim 1, wherein the adhesive layer comprises a pressure sensitive adhesive.

8. The electronic apparatus of claim 1, wherein the polarizing plate further comprises a polarizing layer between the first layer and the second layer, and the polarizing layer comprises polyvinyl alcohol.

9. The electronic apparatus of claim 1, wherein the polarizing plate comprises a triacetylcellulose layer, a polyolefin film on the triacetylcellulose layer, and a protective film on the polyolefin film, the triacetylcellulose layer being the first layer, the polyolefin film being the second layer, and the protective film being the third layer, and
wherein a side surface of the polyolefin film adjacent to the straight sides, when viewed in cross-section, differs from a side surface of the polyolefin film adjacent to the corner sides when viewed in cross-section”.

10. A method, comprising:
providing a display panel;
providing a window comprising a first area and a second area around an edge of the first area in plan view and comprising a perimeter comprising four straight sides and four corner sides arranged between the straight sides and connecting the straight sides adjacent to each other in plan view;
sequentially laminating an adhesive layer and an optical layer on the window to form a preliminary window module;
cutting the preliminary window module to form a window module; and
bonding the display panel to the window module,
wherein the cutting of the preliminary window module to form the window module comprises:
performing a first irradiation operation to irradiate a first laser beam along a first irradiation line defined along the second area;
performing a second irradiation operation to irradiate a second laser beam along a second irradiation line defined along the second area; and
performing a third irradiation operation to irradiate a third laser beam along a third irradiation line defined along the second area,
wherein at least one selected from among the first, second, and third irradiation lines comprises a portion separated from the other irradiation lines, the separated portion overlapping each of the corner sides in plan view, and
wherein the method is a method of manufacturing an electronic apparatus.

11. The method of claim 10, wherein a separation distance of the separated portion from the other irradiation lines varies depending on a curvature of the corner sides in plan view.

12. The method of claim 10, wherein,
the second irradiation operation is performed after the first irradiation operation,
the third irradiation operation is performed after the second irradiation operation,
a power of the second laser beam is less than a power of the first laser beam, and a power of the third laser beam is less than the power of the second laser beam.

13. The method of claim 12, wherein the second irradiation line is located farther from the first area than the first irradiation line is, and the third irradiation line coincides with the first irradiation line.

14. The method of claim 12, wherein the second irradiation line is located closer to the first area than first irradiation line is, and the third irradiation line coincides with the first irradiation line.

15. The method of claim 12, wherein the second irradiation line coincides with the first irradiation line, and the third irradiation line is located farther from the first area than the first irradiation line is.

16. The method of claim 12, wherein the second irradiation line coincides with the first irradiation line, and the third irradiation line is located closer to the first area than the first irradiation line is.

17. The method of claim 10, wherein the optical layer comprises a phase retardation layer, a triacetylcellulose layer on the phase retardation layer, a polyolefin film on the triacetylcellulose layer, and a protective film on the polyolefin film, and
wherein a first depth to which the first laser beam reaches is greater than a distance between an upper surface of the optical layer and an upper surface of the polyolefin film.

18. The method of claim 17, wherein a portion of the triacetylcellulose layer is vaporized by an energy of the first laser beam, and a curved portion is formed in the polyolefin film due to a gas generated by the vaporization of the portion of the triacetylcellulose layer.

19. The method of claim 17, wherein a second depth to which the second laser beam reaches is greater than a distance between the upper surface of the optical layer and an upper surface of the phase retardation layer.

20. The method of claim 17, wherein a third depth to which the third laser beam reaches is smaller than a distance between the upper surface of the optical layer and a lower surface of the adhesive layer.
